(19) United States
(12) Patent Application Publication
(10) Pub. No.: US 2004/0080036 A1
(43) Pub. Date: Apr. 29, 2004

(54) System in package structure

(75) Inventors: Ching-Hui Chang, Kaohsiung (TW); Shih-Chang Lee, Kaohsiung (TW); Wei-Chang Tai, Kaohsiung (TW); Gwo-Liang Weng, Kaohsiung (TW); Cheng-Yin Lee, Tainan (TW)

Correspondence Address: BACON & THOMAS, PLLC, 625 SLATERS LANE, FOURTH FLOOR, ALEXANDRIA, VA, 22314

(73) Assignee: Advanced Semiconductor Engineering, Inc., Kaoshiung (TW)

(21) Appl. No.: 10/690,743

(22) Filed: Oct. 23, 2003

(30) Foreign Application Priority Data
Oct. 24, 2002 (TW) 091124814

(51) Int. Cl. H01L 23/02; H01L 23/10

(52) U.S. Cl. 257/686; 257/706; 257/707; 257/717

(57) ABSTRACT

A system in package structure includes a first substrate, a first chip, a first heat-dissipating component, a second substrate, and a second chip. In this case, the first chip is formed on and electrically connected to the first substrate, and the first heat-dissipating component having a heat-conducting portion is formed above the first chip. The second chip is formed on and electrically connected to the second substrate. The second substrate is set above the first heat-dissipating component and electrically connected to the first substrate.

### BACKGROUND OF THE INVENTION

1. Field of Invention

The invention relates to a semiconductor package structure and, in particular, to a system in package structure having a heat-dissipating component.

2. Related Art

Portable electronic devices with powerful functions, such as cell phones, personal digital assistants (PDAs), and digital cameras, require light and compact package structures with short signal transmission paths. System in package structures implement a stacked chip design to integrate the various functions of the electronic devices. In this case, at least one integrated circuit (IC) is assembled in a single package structure by way of a vertical stacking method, thus reducing package dimensions, decreasing signal distortion and signal delay, and minimizing power loss.

Referring to FIGS. 1A and 1B, a conventional system in package structure 1 includes a first substrate 11, a first chip 12, an electrical connection board 13, a second substrate 14, a second chip 15 and a heat-dissipating component 16. The first chip 12 is formed on and electrically connected to the first substrate 11. The second chip 15 is formed on and electrically connected to the second substrate 14. The second substrate 14 is located over the first chip 12. The electrical connection board 13 has an opening and is provided between the first substrate 11 and the second substrate 14. The heat-dissipating component 16 is formed on the second chip 15. In this case, the first substrate 11 and second substrate 14 are both BGA substrates, and the first chip 12 and second chip 15 are respectively formed on the first substrate 11 and second substrate 14 by flip-chip attachment. The electrical connection board 13 electrically connects the first substrate 11 to the second substrate 14, thus integrating the functions of the first chip 12 and second chip 15. Therefore, the system in package structure 1 can serve as a system.

Alternatively, those skilled in the art may employ wire-bonding technology to electrically connect each chip to the corresponding substrate. Furthermore, a molding process can then be performed to encapsulate the chips with molding compounds. Variant substrates, such as cavity up substrates, can be used to carry the chips. With reference to FIG. 2, another conventional system in package structure 2 is illustrated, wherein the first substrate 11 is a cavity up substrate. The first chip 12 is attached to the cavity of the first substrate 11, and the second chip 15 is attached to the second substrate 14. A wire-bonding process is then performed to electrically connect the second chip 15 to the second substrate 14. Thus, the second chip 15 is electrically connected to the second substrate 14 with a plurality of wires. A molding compound 17 is then formed to encapsulate the second chip 15 for protecting the wires and the second chip 15. The heat-dissipating component 16 is located on the second chip 15, and the molding compound 17 is provided at the inside and outside of the heat-dissipating component 16.

Semiconductor chips are highly integrated, and the amount of heat generated increases in relation to integration. Put simply, as package structures become more compact, heat accumulated therein results in increased heat flux density. To efficiently dissipate heat from the interior of the package structure, it is necessary to provide a heat-dissipating component within the package structure.

In the conventional system in package structure, such as the system in package structure 1 or 2, only one heat-dissipating component 16 is provided on the top chip. Heat generated from the lower chip, however, is not efficiently dissipated. Thus during the operation of the conventional system in package structure, the lower chip may generate excessive heat, resulting in malfunctions or diminished product life.

Therefore, it is an important subjective to provide a system in package structure that efficiently dissipates heat from the lower chip, so that the system in package structure operates normally and has enhanced product life.

### SUMMARY OF THE INVENTION

In view of the above-mentioned problems, an objective of the invention is to provide a system in package structure, which can dissipates heat from the lower chip efficiently.

To achieve the above-mentioned objective, a system in package structure of the invention includes a first substrate, a first chip, a first heat-dissipating component, a second substrate, and a second chip. In the invention, the first chip is formed on and electrically connected to the first substrate. The first heat-dissipating component is formed above the first chip, and has a heat-conducting portion to increase heat-dissipation efficiency. The second chip is formed on and electrically connected to the second substrate, which is set above the first heat-dissipating component and electrically connected to the first substrate.

As mentioned above, heat generated from the first chip (the lower chip) can be dissipated efficiently via the first heat-dissipating component and the heat-conducting portion. Furthermore, the heat-conducting portion may connect to an additional heat-dissipating component so as to dissipate the heat of the first chip via the additional heat-dissipating component. In addition, the heat-conducting portion may protrude and connect to thermal traces of the first and second substrates, so that heat from first chip can be dissipated via the heat-conducting portion, first substrate, and second substrate.

Therefore, the system in package structure of the invention can efficiently dissipate heat from the first chip, so that the system in package structure functions normally and has enhanced product life.

### BRIEF DESCRIPTION OF THE DRAWINGS

The invention will become more fully understood from the detailed description given in the herein below illustrations only, and thus is not limitative of the present invention, and wherein:

FIG. 1A is a schematic illustration showing a conventional system in package structure, wherein each chip is formed on the substrate by flip-chip attachment;

FIG. 1B is an exploded view showing the conventional system in package structure of FIG. 1A;

FIG. 2 is a schematic illustration showing another conventional system in package structure, wherein each chip is formed on the substrate by a wire-bonding technology;

FIG. 3 is a schematic illustration showing a system in package structure according to a preferred embodiment of the invention, wherein the first heat-dissipating component protrudes out of the first substrate;

FIG. 4 is a schematic illustration showing the first heat-dissipating component of the system in package structure of FIG. 3;

FIG. 5 is a schematic illustration showing a system in package structure according to another preferred embodiment of the invention, wherein the first substrate is a cavity up BGA substrate;

FIG. 6 is a schematic illustration showing a system in package structure according to an additional preferred embodiment of the invention, wherein an electrical connection board is employed to electrically connect the first substrate to the second substrate;

FIG. 7 is a schematic illustration showing a system in package structure according to an additional preferred embodiment of the invention, wherein the second substrate has a plurality of second thermal traces; and

FIG. 8 is a schematic illustration showing a system in package structure according to another preferred embodiment of the invention, wherein the first substrate has a plurality of first thermal traces.

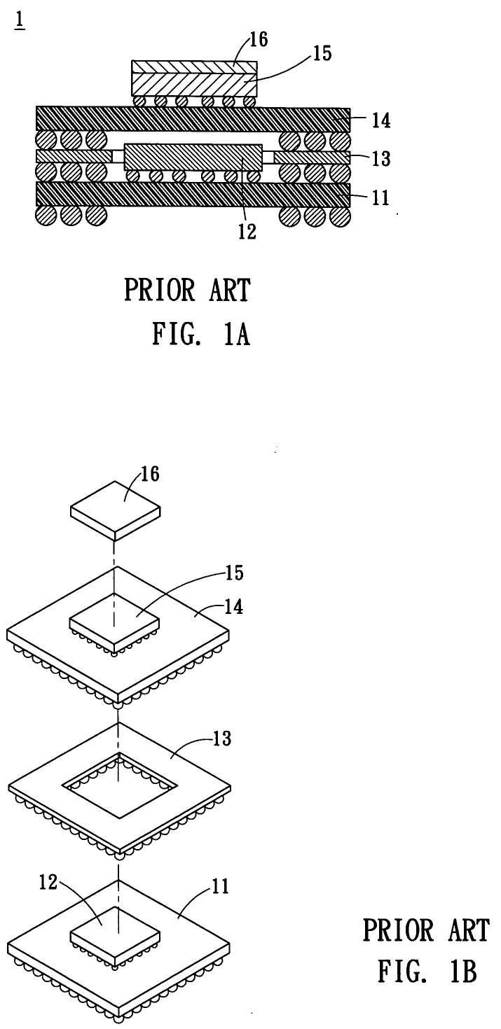

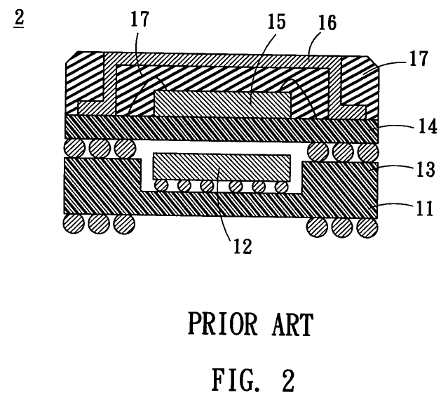

### DETAILED DESCRIPTION OF THE INVENTION

The system in package structure according to the preferred embodiments of the invention will be described herein below with reference to the accompanying drawings, wherein the same reference numbers refer to the same elements.

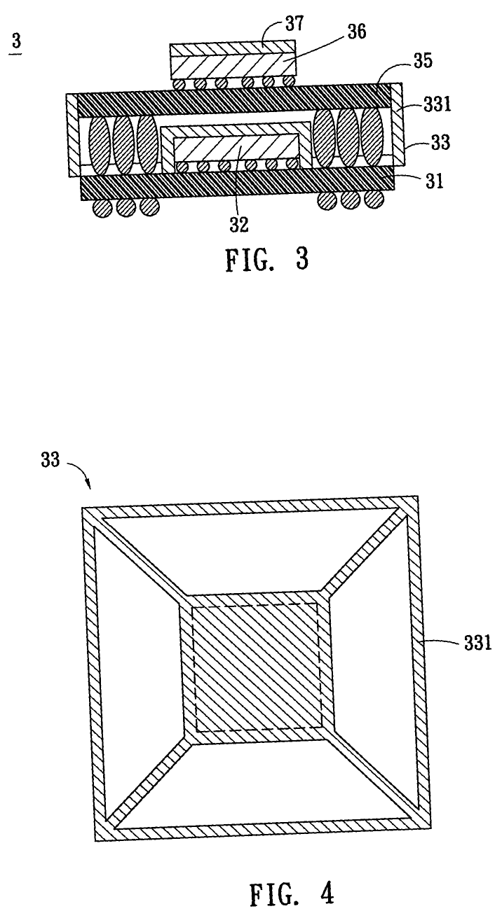

With reference to FIG. 3, a system in package structure 3 includes a first substrate 31, a first chip 32, a first heat-dissipating component 33, a second substrate 35, a second chip 36, and a second heat-dissipating component 37.

In the embodiment, the first substrate 31 and second substrate 35 are both BGA substrates. It should be noted that the first substrate 31 or the second substrate 35 could be any substrate suitable for utilizing in a system in package structure, such as a BGA substrate, or cavity up BGA substrate.

The first chip 32 is formed on the first substrate 31, and the second chip 36 is formed on the second substrate 35. In the current embodiment, the first chip 32 and the second chip 36 are respectively formed on the first substrate 31 and the second substrate 35 by flip-chip attachment. It should be noted that the first chip 32 and the second chip 36 can also be formed on the first substrate 31 and the second substrate 35 by a wire-bonding technology. As mentioned above, after the wire-bonding process is performed to form wires to connect each chip to the corresponding substrate, a subsequent molding process is performed to form a molding compound to encapsulate the chip and wires (not shown).

The first heat-dissipating component 33 is provided on the first chip 32, and the second heat-dissipating component 37 is formed on the second chip 36. In this embodiment, the first heat-dissipating component 33 has a heat-conducting portion 331, which protrudes out of the first substrate 31. As shown in FIG. 4, the first heat-dissipating component 33 is an integrated thin metallic plate. Alternatively, the heat-conducting portion 331 can be welded to the first heat-dissipating component 33. As a result, the heat generated from the first chip 32 can be dissipated efficiently via the protruded heat-conducting portion 331. It should be noted that since the second chip 36 is positioned on top of the system in package structure 3, heat from the second chip 36 is sufficiently dissipated even if the second heat-dissipating component 37 is removed.

Referring to FIG. 3, again, a plurality of bumps are formed between the first substrate 31 and second substrate 35. Thus, the bumps can electrically connect the first substrate 31 and second substrate 35. For example, the bumps are formed underneath the second substrate 35, and a plurality of pads are formed on the first substrate 31. The bumps are directly connected to the pads, and the circuitry of the first substrate 31 can thus electrically connect to that of the second substrate 35, resulting in integration of the functions of the first chip 32 and second chip 36 to carry out the required system efficiency. In the present embodiment, the thickness of the bumps must be larger than the sum of the thickness of the first chip 32 and the first heat-dissipating component 33.

As mentioned above, the first substrate can be a cavity up BGA substrate having a cavity. As shown in FIG. 5, a system in package structure 5 according to an additional embodiment of the invention includes a first substrate 31′, a first chip 32, a first heat-dissipating component 33, a second substrate 35, a second chip 36, and a second heat-dissipating component 37. In this embodiment, since the first substrate 31′ is a cavity up BGA substrate, the first chip 32 is provided in a central cavity of the first substrate 31′. Thus, the thickness of the bumps of the second substrate 35 is unnecessary to be larger than the sum of the thickness of the first chip 32 and the first heat-dissipation component 33.

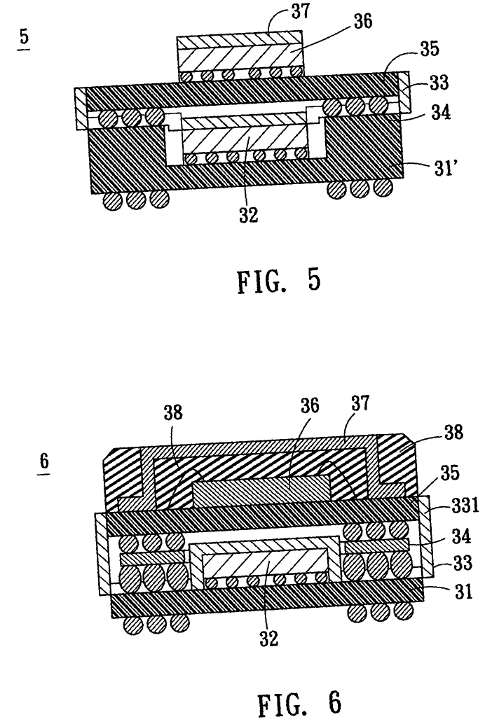

Furthermore, the first and second substrate may electrically connect to one another with an electrical connection board 34, and the second chip may be formed on the second substrate by wire-bonding technology. Referring to FIG. 6, a system in package structure 6 according to an additional embodiment of the invention includes a first substrate 31, a first chip 32, a first heat-dissipating component 33, an electrical connection board 34, a second substrate 35, a second chip 36, a second heat-dissipating component 37, and a molding compound 38. In the current embodiment, the second chip 36 is formed on the second substrate 35, and electrically connected to the second substrate 35 by wire-bonding technology. In other words, a plurality of wires are formed to electrically connect the second chip 36 to the second substrate 35. The molding compound 38 encapsulates the second chip 36 for protecting the wires and the second chip 36. The second heat-dissipating component 37 is formed above the second chip 36, and the molding compound 38 is provided at the inside and outside of the heat-dissipating component 37. The electrical connection board 34 is provided between the first substrate 31 and the second substrate 35 for electrically connecting the pads of the first substrate 31 to the bumps of the second substrate 35. In detail, the system in package structure 6 includes a plurality of first bumps for electrically connecting the electrical connection board 34 and the first substrate 31. The system in package structure 6 further includes a plurality of second bumps for electrically connecting the electrical connection board 34 and the second substrate 35. Therefore, signals can be transmitted between the first substrate 31 and the second substrate 35 via the electrical connection board 34. The functions of the first chip 32 and second chip 36 can then be integrated enabling normal system operation.

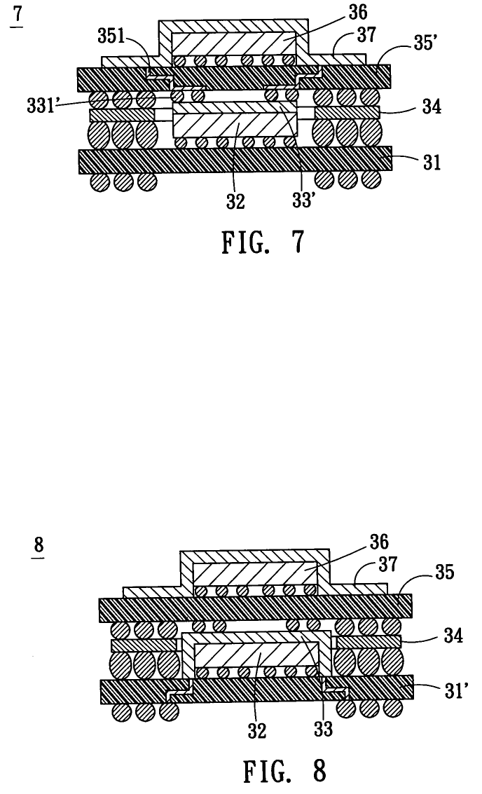

With reference to FIG. 7, a system in package structure 7 according to an additional embodiment of the invention includes a first substrate 31, a first chip 32, a first heat-dissipating component 33′, an electrical connection board 34, a second substrate 35′, a second chip 36, and a second heat-dissipating component 37.

In the embodiment, the first substrate 31, first chip 32, electrical connection board 34, second chip 36, and second heat-dissipating component 37 are as those mentioned above.

The first heat-dissipating component 33′ is formed on the first chip 32, wherein the heat conducting portion 331′ of the first heat-dissipating component 33′ comprises a plurality of heat-conducting balls. The upper portions of the heat-conducting balls may contact to the lower surface of the second substrate 35′.

The second substrate 35′ is set on the heat conducting portion 331′ of the first heat-dissipating component 33′, and electrically connected to the first substrate 31 via the electrical connection board 34. In this embodiment, the heat-conducting portion 331′ comprises a plurality of solder balls, which do not have signal transmission functions. The second substrate 35′ further includes a plurality of second thermal traces 351. One end of each second thermal trace 351 contacts the second heat-dissipating component 37, while the other end contacts heat-conducting portion 331′ of the first heat-dissipating component 33′. Thus, heat generated from the first chip 32 can be efficiently dissipated via the first heat-dissipating component 33′, the second thermal traces 351 and the second heat-dissipating component 37 sequentially.

With reference to FIG. 8, in a further embodiment of the invention, a system in package structure 8 includes a first substrate 31′, a first chip 32, a first heat-dissipating component 33, an electrical connection board 34, a second substrate 35, a second chip 36, and a second heat-dissipating component 37. In this embodiment, the first substrate 31′ includes a plurality of first thermal traces connecting the first heat-dissipation component 33. Thus, the heat dissipation efficiency can be enhanced.

In summary, since the system in package structure of the invention has the first heat-dissipating component provided on the first chip, and efficiently dissipates heat generated by the first chip (lower chip). Thus, the system in package structure of the invention can operate normally and have enhanced product life.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A system in package structure, comprising:
a first substrate;
a first chip, which is formed on and electrically connected to the first substrate;
a first heat-dissipation component having a heat-conducting portion, which is formed above the first chip;
a second substrate, which is set above the first heat-dissipating component and electrically connected to the first substrate; and
a second chip, which is formed on and electrically connected to the second substrate.

2. The system in package structure of claim 1, further comprising a second heat-dissipating component formed above the second chip.

3. The system in package structure of claim 1, wherein the first substrate has a plurality of first thermal traces and the first heat-dissipation component is connected to the first thermal traces.

4. The system in package structure of claim 1, wherein the second substrate has a plurality of second thermal traces, and the heat-conducting portion protrudes upwardly to contact the second thermal traces.

5. The system in package structure of claim 1, wherein the first heat-dissipating component and the heat-conducting portion are an integrally formed metallic thin plate.

6. The system in package structure of claim 1, wherein the first substrate is a cavity substrate having a cavity and the first chip is disposed in the cavity.

7. The system in package structure of claim 1, wherein at least one bump is formed between the first substrate and the second substrate and electrically connects the first substrate and the second substrate.

8. The system in package structure of claim 1, further comprising an electrical connection board provided between the first substrate and the second substrate, and electrically connected the first substrate and the second substrate.

9. The system in package structure of claim 8, further comprising a first bump for electrically connecting the electrical connection board and the first substrate.

10. The system in package structure of claim 8, further comprising a second bump for electrically connecting the electrical connection board and the second substrate.
